(19) United States
(12) Patent Application Publication
(10) Pub. No.: US 2013/0305957 A1
(43) Pub. Date: Nov. 21, 2013

(54) CLOUD SERVER ASSEMBLY

(71) Applicant: HON HAI PRECISION INDUSTRY CO., LTD., New Taipei (TW)

(72) Inventor: Feng-Chi YANG, New Taipei (TW)

(73) Assignee: HON HAI PRECISION INDUSTRY CO., LTD., New Taipei (TW)

(21) Appl. No.: 13/865,631

(22) Filed: Apr. 18, 2013

(30) Foreign Application Priority Data
May 18, 2012 (CN) 201220224444.X

(51) Int. Cl. H05K 7/20

(52) U.S. Cl. CPC H05K 7/20763
USPC 105/238.1

(57) ABSTRACT

A cloud server assembly includes at least one cloud server, at least one carriage, and a track. The at least one cloud server is located in the at least one carriage. The carriage moves at high-speed along the track under external force.

### BACKGROUND

1. Technical field

The disclosure generally relates to cloud server assemblies.

2. Description of the Related Art

Generally, cloud servers use a large amount of water for heat dissipation. Tap water is expensive and difficult to amass in large quantity, thus, in order to get enough water, the cloud servers may be located adjacent to lakes or oceans. However, areas adjacent to lakes or oceans are highly vulnerable to flood or typhoon, and the cloud servers may be damaged.

Therefore, there is room for improvement within the art.

### BRIEF DESCRIPTION OF THE DRAWINGS

Many aspects of an exemplary cloud server assembly can be better understood with reference to the following drawing. The components in the drawing are not necessarily drawn to scale, the emphasis instead being placed upon clearly illustrating the principles of the exemplary cloud server assembly. Moreover, in the drawing, like reference numerals designate corresponding parts throughout the several views. Wherever possible, the same reference numbers are used throughout the drawing to refer to the same or like elements of an embodiment.

FIG. 1 is a schematic view of a cloud server assembly according to an exemplary embodiment, during assembly.

FIG. 2 is a schematic view illustrating a location of the track shown in FIG. 1.

### DETAILED DESCRIPTION

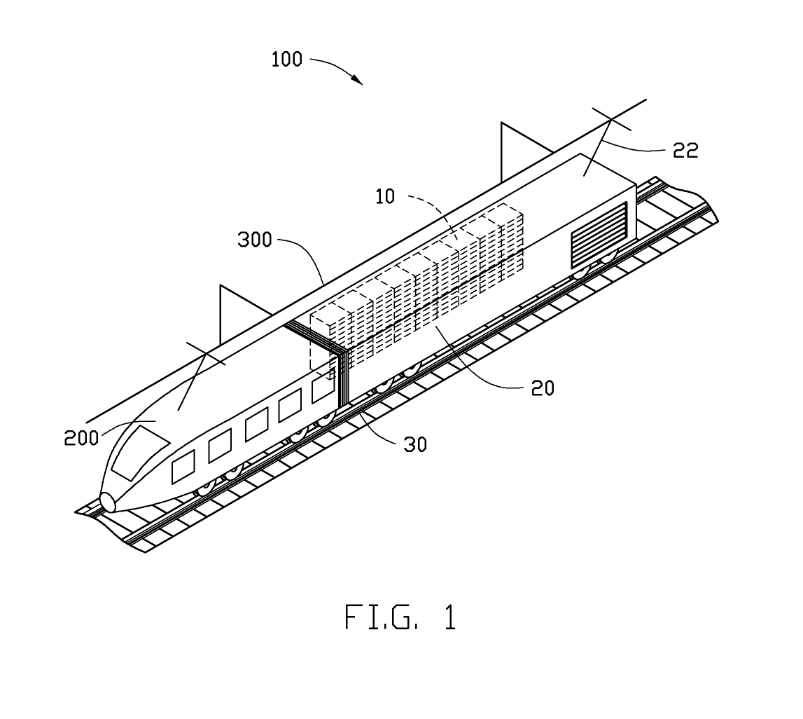

FIG. 1 shows a cloud server assembly 100 according to an exemplary embodiment. The cloud server assembly 100 includes a plurality of cloud servers 10, a plurality of carriages 20, and a track 30. Each cloud server 10 is located in one of the plurality of carriages 20. The plurality of carriages 20 are separately located on the track 30. The plurality of carriages 20 can also be interconnected. To describe the cloud assembly 100 clearly, the drawing only shows one carriage 20. In the embodiment, the track 30 is a high-speed track, and a locomotive 200 can drive the carriage 20 to move at high-speed along the track 30.

The carriage 20 includes a radiator (not shown) and a pantograph 22. The radiator is configured for importing water from water source, such as lakes or oceans, and the water dissipates heat of the carriage 20. The pantograph 22 is electronically connected to an external wire 300 to supply power to the plurality of cloud servers 10.

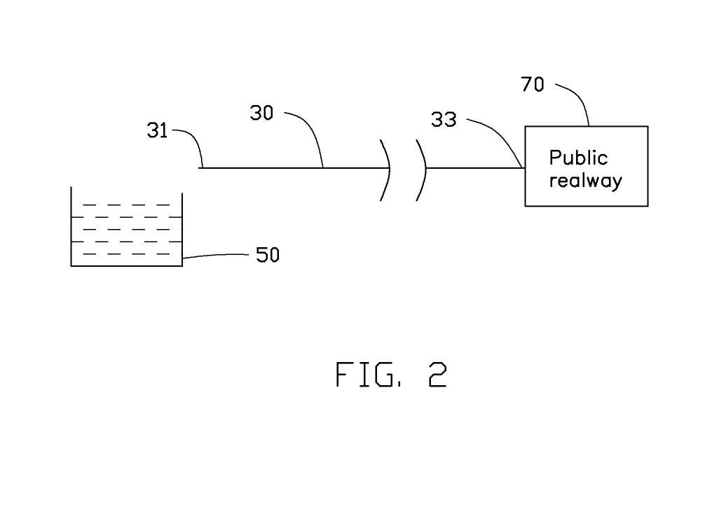

Referring to FIG. 2, a first end 31 of the track 30 is located adjacent to a water source 50, such as lakes or oceans with abundant water, and a second end 33 of the track 30 away from the water source 50 can be connected to a public railway 70.

Normally, the carriage 20 with the cloud server 10 is located at the first end 31 of the track 30 adjacent to the water source 50. When flood or typhoon comes, the locomotive 200 drives the carriage 20 with the cloud server 10 to move at high-speed toward the second end 33 of the track 30, and then the carriage 20 with the cloud server 10 leaves the region affected by flood or typhoon to prevent the cloud server 10 from damaging.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. A cloud server assembly comprising:
at least one cloud server;
at least one carriage; and
a track;
wherein the at least one cloud server is located in the at least one carriage; and the carriage can move at high-speed along the track under external force.

2. The cloud server assembly as claimed in claim 1, wherein the at least one carriage comprises a pantograph electronically connected to an external wire, the pantograph supplies power to the at least one cloud server.

3. The cloud server assembly as claimed in claim 1, wherein the track comprises a first end located adjacent to a water source with abundant water and a second end away from the water source.

4. The cloud server assembly as claimed in claim 3, wherein the second end of the track connects to a public railway.

5. The cloud server assembly as claimed in claim 1, wherein a locomotive drives the carriage to move at high-speed along the track.

6. A cloud server assembly comprising:
at least one carriage;
at least one cloud server located in the at least one carriage; and
a track;
wherein the carriage is driven to move at high-speed along the track by a locomotive.

7. The cloud server assembly as claimed in claim 6, wherein the at least one carriage comprises a pantograph electronically connected to external wire, the pantograph supplies power to the at least one cloud server.

8. The cloud server assembly as claimed in claim 6, wherein the track comprises a first end located adjacent to a water source with abundant water and a second end away from the water source.

9. The cloud server assembly as claimed in claim 8, wherein the second end of the track connects to a public railway.
